(19) United States
(12) Patent Application Publication
(10) Pub. No.: US 2024/0250662 A1
(43) Pub. Date: Jul. 25, 2024

(54) Vibrator Device

(71) Applicant: SEIKO EPSON CORPORATION, Tokyo (JP)

(72) Inventor: Atsushi TANAKA, Minowa (JP)

(21) Appl. No.: 18/420,833

(22) Filed: Jan. 24, 2024

(30) Foreign Application Priority Data
Jan. 25, 2023 (JP) 2023-009434

(51) Int. Cl. H03H 9/19; H03B 5/04; H03H 9/05; H03H 9/10

(52) U.S. Cl. CPC H03H 9/19; H03B 5/04; H03H 9/0557; H03H 9/1021

(57) ABSTRACT

A vibrator device includes: a vibrator; and a circuit device disposed apart from the vibrator, in which the circuit device includes a drive circuit configured to drive the vibrator, a temperature sensor configured to generate a temperature signal corresponding to a detected temperature, a temperature compensation circuit configured to compensate for temperature characteristics of a drive state of the vibrator based on the temperature signal, a heat source circuit configured to operate in a first state or in a second state in which current consumption is different from current consumption in the first state, and a transient response compensation circuit configured to compensate for, when the first state and the second state of the heat source circuit are switched, a difference between a transient response of a temperature detected by the temperature sensor and a transient response of a temperature of the vibrator.

The present application is based on, and claims priority from JP Application Serial Number 2023-009434, filed Jan. 25, 2023, the disclosure of which is hereby incorporated by reference herein in its entirety.

### BACKGROUND

### 1. Technical Field

The present disclosure relates to a vibrator device.

### 2. Related Art

JP-A-2012-156977 discloses a temperature compensated crystal oscillator that includes a temperature sensor, a temperature compensation circuit, and a plurality of output buffers in an IC chip, in which as viewed from a quartz crystal connection terminal having a phase opposite to that of an output of an output buffer that can be subjected to on/off control, an output terminal of the output buffer is disposed at a position farther than an output terminal of an output buffer that is not subjected to on/off control. According to the temperature compensated crystal oscillator disclosed in JP-A-2012-156977, wraparound of an oscillation frequency component to an oscillation circuit side is reduced, and it is possible to reduce fluctuations in an oscillation frequency due to the on/off control over the output buffer.

JP-A-2012-156977 is an example of the related art.

However, in the temperature compensated crystal oscillator disclosed in JP-A-2012-156977, when the output buffer is switched on or off and a heat generation amount of the output buffer rapidly changes, the temperature sensor inside the IC rapidly detects a temperature change, whereas a temperature change in a vibrator that is separate from the IC chip is delayed, and thus an error may occur in a temperature compensation, and the oscillation frequency may fluctuate.

### SUMMARY

An aspect of a vibrator device according to the present disclosure includes:
a vibrator; and
a circuit device disposed apart from the vibrator, in which
the circuit device includes
   a drive circuit configured to drive the vibrator,
   a temperature sensor configured to generate a temperature signal corresponding to a detected temperature,
   a temperature compensation circuit configured to compensate for temperature characteristics of a drive state of the vibrator based on the temperature signal,
   a heat source circuit configured to operate in a first state or in a second state in which current consumption is different from current consumption in the first state, and
   a transient response compensation circuit configured to compensate for, when the first state and the second state of the heat source circuit are switched, a difference between a transient response of a temperature detected by the temperature sensor and a transient response of a temperature of the vibrator.

### BRIEF DESCRIPTION OF THE DRAWINGS

FIG. 1 is a diagram showing a functional configuration of a vibrator device.

FIG. 2 is a perspective view of the vibrator device according to a first embodiment.

FIG. 3 is a cross-sectional view of the vibrator device according to the first embodiment.

FIG. 4 is a functional block diagram of the vibrator device according to the first embodiment.

FIG. 5 is a diagram showing an example of a timing chart of writing and reading data to and from a memory.

FIG. 6 is a diagram showing a heat propagation path when an output circuit is switched from a first state to a second state.

FIG. 7 is a diagram showing a thermal network based on the propagation path in FIG. 6.

FIG. 8 is a diagram showing an example of changes over time in a transient response of a temperature and in a frequency deviation when the output circuit is switched from the first state to the second state.

FIG. 9 is a functional block diagram of the vibrator device according to a second embodiment.

FIG. 10 is a diagram showing a configuration example of a temperature compensation circuit and a PLL circuit.

FIG. 11 is a cross-sectional view of the vibrator device according to a modification.

### DESCRIPTION OF EMBODIMENTS

Hereinafter, preferred embodiments of the present disclosure will be described in detail with reference to the drawings. The embodiments to be described below do not unduly limit contents of the present disclosure described in the claims. All configurations described below are not necessarily essential components of the present disclosure.

### 1. Functional Configuration of Vibrator Device

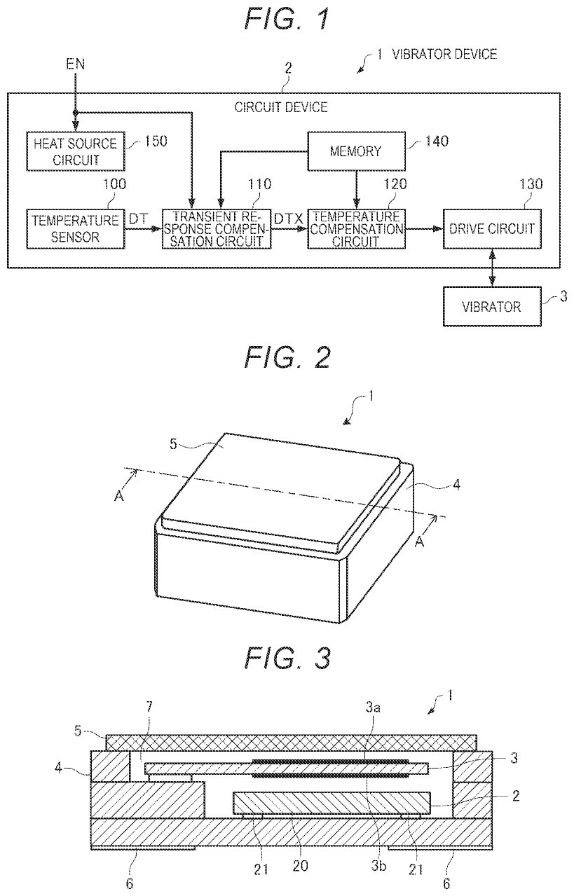

FIG. 1 is a diagram showing a functional configuration of a vibrator device according to the embodiment. As shown in FIG. 1, a vibrator device 1 according to the embodiment includes a circuit device 2 and a vibrator 3. The circuit device 2 and the vibrator 3 are housed in a package (not shown).

The circuit device 2 includes a temperature sensor 100, a transient response compensation circuit 110, a temperature compensation circuit 120, a drive circuit 130, a memory 140, and a heat source circuit 150. The circuit device 2 may have a configuration in which some of these elements are omitted or changed, or other elements are added.

The drive circuit 130 drives the vibrator 3 to vibrate the vibrator 3.

The temperature sensor 100 detects a temperature and generates a temperature signal DT corresponding to the detected temperature. The temperature signal DT may be a digital signal.

The temperature compensation circuit 120 compensates for temperature characteristics of a drive state of the vibrator 3 based on the temperature signal DT generated by the temperature sensor 100. Specifically, the memory 140 stores temperature compensation data TCD for compensating for the temperature characteristics of the drive state of the vibrator 3, and the temperature compensation circuit 120 compensates for the temperature characteristics of the drive state of the vibrator 3 based on the temperature signal DT and the temperature compensation data TCD.

The heat source circuit 150 is a circuit that generates heat when the heat source circuit 150 operates, and operates in a first state or in a second state in which current consumption is different from that in the first state. A heat generation amount when the heat source circuit 150 operates in the first state is different from a heat generation amount when the heat source circuit 150 operates in the second state. For example, in a case in which current consumption when the heat source circuit 150 operates in the second state is larger than current consumption when the heat source circuit 150 operates in the first state, a heat generation amount when the heat source circuit 150 operates in the second state is larger than a heat generation amount when the heat source circuit 150 operates in the first state. Therefore, in this case, when the heat source circuit 150 is switched from the first state to the second state, the heat generation amount of the heat source circuit 150 increases. When the heat source circuit 150 switches from the second state to the first state, the heat generation amount of the heat source circuit 150 decreases. Conversely, in a case in which current consumption when the heat source circuit 150 operates in the second state is smaller than current consumption when the heat source circuit 150 operates in the first state, a heat generation amount when the heat source circuit 150 operates in the second state is smaller than the heat generation amount when the heat source circuit 150 operates in the first state. Therefore, in this case, when the heat source circuit 150 is switched from the first state to the second state, the heat generation amount of the heat source circuit 150 decreases. When the heat source circuit 150 switches from the second state to the first state, the heat generation amount of the heat source circuit 150 increases.

When the heat source circuit 150 switches between the first state and the second state, the transient response compensation circuit 110 compensates for a difference between a transient response of a temperature detected by the temperature sensor 100 and a transient response of a temperature of the vibrator 3. For example, when the heat generation amount of the heat source circuit 150 increases before and after switching between the first state and the second state of the heat source circuit 150, heat is propagated from the heat source circuit 150 to the temperature sensor 100 and a temperature of the temperature sensor 100 rises, and heat is propagated from the heat source circuit 150, via a package, to the vibrator 3 and the temperature of the vibrator 3 rises. Conversely, when the heat generation amount of the heat source circuit 150 decreases before and after switching between the first state and the second state of the heat source circuit 150, heat is propagated from the temperature sensor 100 to the heat source circuit 150 and the temperature of the temperature sensor 100 decreases, and heat is propagated from the vibrator 3, via the package, to the heat source circuit 150 and the temperature of the vibrator 3 decreases. At this time, since the temperature sensor 100 and the heat source circuit 150 are in the circuit device 2, heat rapidly propagates between the temperature sensor 100 and the heat source circuit 150, whereas the circuit device 2 is disposed apart from the vibrator 3. Therefore, heat propagates between the vibrator 3 and the heat source circuit 150 via the package, and heat propagation becomes slow. Therefore, when the heat source circuit 150 switches between the first state and the second state, the transient response of the temperature detected by the temperature sensor 100 is faster than the transient response of the temperature of the vibrator 3. The transient response compensation circuit 110 compensates for this difference of the transient response.

For example, the temperature signal DT may be a digital signal, and the transient response compensation circuit 110 may include a digital filter that performs filter processing on the temperature signal DT. The digital filter may be a low-pass filter. When the temperature signal DT passes through the digital filter, a group delay occurs according to a cutoff frequency of the digital filter, and an input of the temperature signal DT to the temperature compensation circuit 120 is delayed. As a result, the difference between the transient response of the temperature detected by the temperature sensor 100 and the transient response of the temperature of the vibrator 3 is compensated for, and temperature compensation accuracy attained by the temperature compensation circuit 120 is improved.

The digital filter may operate at a cutoff frequency based on data stored in the memory 140. That is, the cutoff frequency of the digital filter may be variable according to data stored in the memory 140 in advance.

When a temperature outside the package of the vibrator device 1 changes, a difference between a heat propagation time between the temperature sensor 100 and outside air and a heat propagation time between the vibrator 3 and the outside air is small. Therefore, when the transient response compensation circuit 110 is always operating, if an outside air temperature changes while the heat source circuit 150 remains unchanged in the first state or the second state, excessive temperature compensation is performed by the temperature compensation circuit 120. Therefore, it is preferable that the transient response compensation circuit 110 stops operating after a predetermined period elapses after the heat source circuit 150 is switched between the first state and the second state. The predetermined period may be, for example, a period from when the heat source circuit 150 switches between the first state and the second state until the transient response of the temperature of the vibrator 3 converges.

### 2. Specific Example of Vibrator Device

Hereinafter, a temperature compensated oscillator will be described as a specific example of the vibrator device 1 shown in FIG. 1.

### 2-1. First Embodiment

### 2-1-1. Structure of Vibrator Device

FIGS. 2 and 3 are diagrams showing an example of a structure of the vibrator device 1 according to a first embodiment. FIG. 2 is a perspective view of the vibrator device 1. FIG. 3 is an example of a cross-sectional view taken along a line A-A in FIG. 2.

As shown in FIGS. 2 and 3, the vibrator device 1 includes the circuit device 2, the vibrator 3, a package 4, a lid 5, and a plurality of external terminals 6.

In the embodiment, the vibrator 3 is a quartz crystal resonator using a quartz crystal as a substrate material, and is, for example, an AT cut quartz crystal resonator or a tuning fork type quartz crystal resonator. The vibrator 3 may be a SAW resonator or a MEMS vibrator. SAW is an abbreviation for surface acoustic wave. MEMS is an abbreviation for micro electro mechanical systems. As the substrate material for the vibrator 3, in addition to the quartz crystal, a piezoelectric material such as a piezoelectric single crystal formed of lithium tantalate, lithium niobate, or the like, a piezoelectric ceramic formed of lead zirconate titanate or the like, or a silicon semiconductor material can be used. As an excitation unit for the vibrator 3, one based on a piezoelectric effect may be used, or electrostatic drive based on Coulomb force may be used.

In the embodiment, the circuit device 2 is implemented by a one-chip integrated circuit. At least a part of the circuit device 2 may be implemented by a discrete part.

As shown in FIG. 3, the vibrator 3 includes metal excitation electrodes 3a and 3b on a front surface and a back surface of the vibrator 3, and oscillates at a desired frequency according to a shape and mass of the vibrator 3 including the excitation electrodes 3a and 3b.

As shown in FIG. 3, the vibrator device 1 is an oscillator having a single seal structure, and the package 4 houses the circuit device 2 and the vibrator 3 in the same space. For example, the package 4 may be a ceramic package. Specifically, the package 4 is formed with a recess, and the recess is covered with the lid 5 to form a housing chamber 7.

As shown in FIG. 3, a plurality of terminals 21 are provided at a bottom surface 20 of the circuit device 2. A plurality of external terminals are provided at a back surface of the package 4 that is a bottom surface of the vibrator device 1. Interconnects (not shown) for electrically coupling the two terminals 21 of the circuit device 2 and the two excitation electrodes 3a and 3b of the vibrator 3 are provided inside the package 4 or at a front surface of the recess. The circuit device 2 is electrically coupled to the vibrator 3 by the interconnects. Interconnects (not shown) for electrically coupling other terminals 21 of the circuit device 2 and the plurality of external terminals 6 of the vibrator device 1 are provided inside the package 4 or at the front surface of the recess.

### 2-1-2. Configuration of Vibrator Device

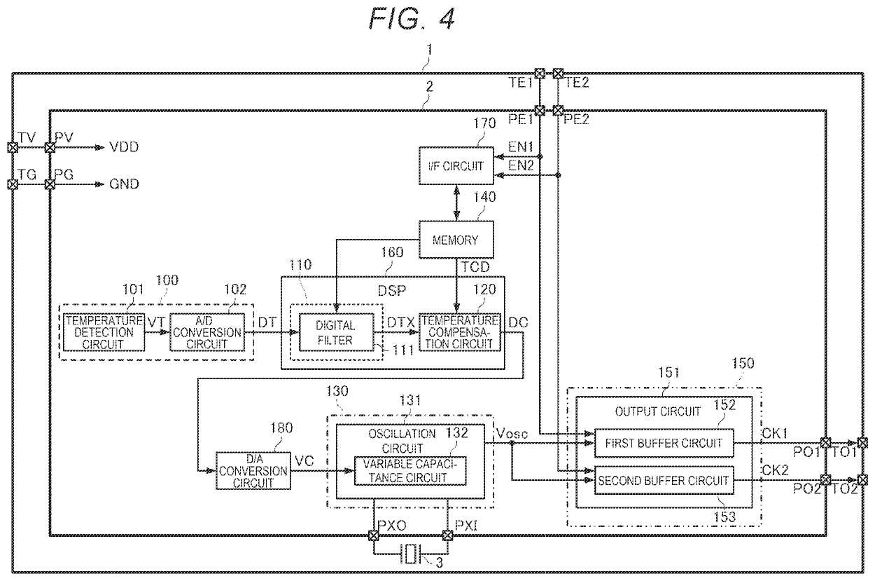

FIG. 4 is a functional block diagram of the vibrator device 1 according to the first embodiment. In FIG. 4, similar components as those in FIG. 1 are denoted by the same reference signs. As shown in FIG. 4, the vibrator device 1 according to the first embodiment includes the circuit device 2 and the vibrator 3. The vibrator device 1 includes, as the six external terminals 6, a TV terminal, a TG terminal, a TO1 terminal, a TO2 terminal, a TE1 terminal, and a TE2 terminal. The circuit device 2 includes, as eight terminals 21, a PV terminal, a PG terminal, a PO1 terminal, a PO2 terminal, a PE1 terminal, a PE2 terminal, a PXI terminal, and a PXO terminal. The PV terminal, the PG terminal, the PO1 terminal, the PO2 terminal, the PE1 terminal, and the PE2 terminal of the circuit device 2 are electrically coupled to the TV terminal, the TG terminal, the TO1 terminal, the TO2 terminal, the TE1 terminal, and the TE2 terminal of the vibrator device 1, respectively. The PXI terminal of the circuit device 2 is electrically coupled to one end of the vibrator 3. The PXO terminal of the circuit device 2 is electrically coupled to the other end of the vibrator 3. The circuit device 2 operates by being supplied with a power supply voltage VDD supplied via the PV terminal from the TV terminal and a ground voltage GND supplied via the PG terminal from the TG terminal.

In the embodiment, the vibrator device 1 includes a temperature detection circuit 101, an A/D conversion circuit 102, a digital filter 111, the temperature compensation circuit 120, an oscillation circuit 131, the memory 140, an output circuit 151, an interface circuit 170, and a D/A conversion circuit 180. The vibrator device 1 may have a configuration in which some of these elements are omitted or changed, or other elements are added.

The oscillation circuit 131 is electrically coupled to both the ends of the vibrator 3 via the PXI terminal and the PXO terminal, and generates an oscillation signal Vosc by oscillating the vibrator 3. Specifically, the oscillation circuit 131 receives a signal output from the vibrator 3 via the PXO terminal, and supplies a signal obtained by amplifying the signal to the vibrator 3 via the PXI terminal. The oscillation circuit 131 includes a variable capacitance circuit 132 functioning as a load capacity, and the oscillation signal Vosc has a frequency corresponding to a capacity value of the variable capacitance circuit 132. The oscillation circuit 131 corresponds to the drive circuit 130 shown in FIG. 1.

The temperature detection circuit 101 detects a temperature and outputs a temperature signal VT that is an analog signal of a voltage corresponding to the detected temperature. For example, the temperature detection circuit 101 may be a circuit using temperature dependence of a forward voltage at a PN junction. The A/D conversion circuit 102 converts the temperature signal VT into the temperature signal DT. The temperature signal VT is an analog signal output from the temperature detection circuit 101. The temperature signal DT is a digital signal. For example, the A/D conversion circuit 102 may be a successive approximation A/D conversion circuit. The temperature detection circuit 101 and the A/D conversion circuit 102 correspond to the temperature sensor 100 shown in FIG. 1.

The digital filter 111 performs filter processing on the temperature signal DT output from the A/D conversion circuit 102. The digital filter 111 may be a low-pass filter.

The temperature compensation circuit 120 compensates for, based on a temperature signal DTX output from the digital filter 111, frequency-temperature characteristics of the oscillation signal Vosc as the temperature characteristics of the drive state of the vibrator 3. Specifically, the temperature compensation data TCD for compensating for the frequency-temperature characteristics of the oscillation signal Vosc is stored in the memory 140, and the temperature compensation circuit 120 generates, based on the temperature signal DTX and the temperature compensation data TCD, a temperature compensation signal DC that is a digital signal. For example, when the frequency-temperature characteristics of the vibrator 3 is a cubic curve, the temperature compensation circuit 120 corrects, based on the temperature compensation data TCD including a coefficient value for each order of the cubic curve that cancels out the frequency-temperature characteristics, a frequency of the oscillation signal Vosc such that the frequency approaches a constant value regardless of the temperature.

The digital filter 111 and the temperature compensation circuit 120 are implemented by, for example, a DSP 160. The DSP is an abbreviation for digital signal processor.

The D/A conversion circuit 180 converts the temperature compensation signal DC into a temperature compensation voltage VC. The temperature compensation signal DC is a digital signal output from the temperature compensation circuit 120. The temperature compensation voltage VC is an analog signal. The temperature compensation voltage VC is applied to the variable capacitance circuit 132 in the oscillation circuit 131, and the variable capacitance circuit 132 has a capacity value corresponding to a magnitude of the temperature compensation voltage VC. An oscillation frequency of the oscillation circuit 131 changes according to the capacity value of the variable capacitance circuit 132. The temperature compensation voltage VC output from the D/A conversion circuit 180 changes according to the temperature detected by the temperature detection circuit 101. As a result, the oscillation frequency of the oscillation circuit 131 is controlled to approach a constant frequency regardless of the temperature.

The memory 140 includes a nonvolatile memory and a register (not shown) that store various types of information. The nonvolatile memory may be, for example, a MONOS memory or an EEPROM. MONOS is an abbreviation for metal oxide nitride oxide silicon. EEPROM is an abbreviation for electrically erasable programmable read-only memory. In a manufacturing process of the vibrator device 1, various types of information for controlling each circuit, for example, data for setting a cutoff frequency and an order of the digital filter 111, and temperature compensation data for controlling the temperature compensation circuit 120 are stored in the nonvolatile memory of the memory 140. When supply of the power supply voltage VDD to a TVD terminal is started, various types of information stored in the nonvolatile memory of the memory 140 is transferred to the register, and various types of information stored in the register is appropriately supplied to each circuit.

When a control signal having a predetermined pattern is received from the TE2 terminal within a predetermined period after the supply of the power supply voltage VDD to the TVD terminal is started, the interface circuit 170 sets an operation mode to an external communication mode after the predetermined period elapses. For example, the interface circuit 170 may set a period from start of oscillation of the vibrator 3 due to the supply of the power supply voltage VDD to detection of stable oscillation as the predetermined period, or may count the number of pulses of the oscillation signal Vosc and determine that the predetermined period elapses when a count value reaches a predetermined value. For example, the interface circuit 170 may measure the predetermined period based on an output signal of an RC time constant circuit, which starts an operation upon supply of the power supply voltage VDD.

In the external communication mode, the interface circuit 170 can perform data communication with an external device (not shown) coupled to the TE1 terminal and the TE2 terminal via the PE1 terminal and the PE2 terminal. According to a predetermined communication standard, the external device outputs a serial clock signal to the TE1 terminal, outputs a serial data signal to the TE2 terminal in synchronization with the serial clock signal, or acquires a signal output from the interface circuit 170, via the PE2 terminal, to the TE2 terminal. In the external communication mode, the interface circuit 170 samples serial data signals as various commands for each edge of the serial clock signal according to, for example, a standard of an I2C bus. I2C is an abbreviation for inter-integrated circuit. The interface circuit 170 performs processing such as setting of an operation mode and writing and reading of data to and from the memory 140 based on the sampled command. In the embodiment, the interface circuit 170 communicates with an external device according to a communication standard of a two-wire bus such as the I2C bus, but may communicate with an external device according to a communication standard of a three-wire bus or a four-wire bus such as an SPI bus. SPI is an abbreviation for serial peripheral interface.

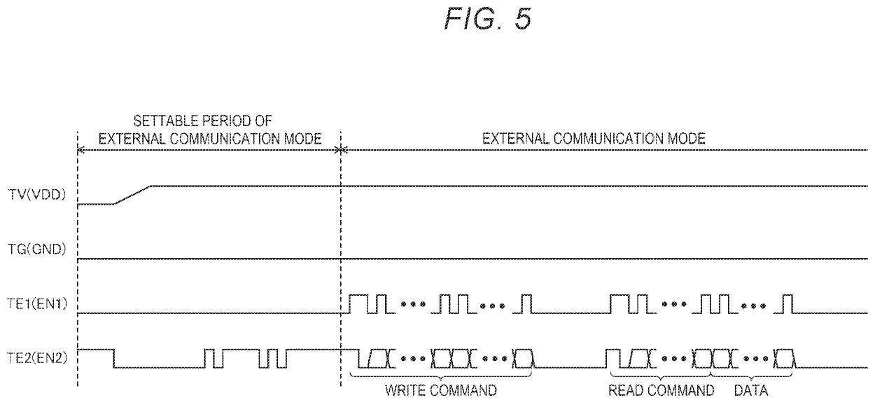

For example, when a write command to the memory 140 is sampled in the external communication mode, the interface circuit 170 writes data designated by the write command to an address of the memory 140 designated by the write command. When a read command from the memory 140 is sampled in the external communication mode, the interface circuit 170 reads data from an address of the memory 140 designated by the read command, converts the data into serial data, and outputs the serial data. FIG. 5 shows an example of a timing chart when writing and reading of data to and from the memory 140 are performed in the external communication mode after shifting to the external communication mode after the supply of the power supply voltage VDD to the TVD terminal is started.

For example, in the external communication mode, when a setting command for a normal operation mode is sampled, the interface circuit 170 shifts the operation mode from the external communication mode to the normal operation mode. In the normal operation mode, the interface circuit 170 supplies signals received from the TE1 terminal and the TE2 terminal via the PE1 terminal and the PE2 terminal to the output circuit 151 as a first enable control signal EN1 and a second enable control signal EN2, respectively. Therefore, in the normal operation mode, outputs of a first output clock signal CK1 from the TO1 terminal and a second output clock signal CK2 from the TO2 terminal are controlled based on signals input to the TE1 terminal and the TE2 terminal.

When a signal having a predetermined pattern is not received from the TE2 terminal within a predetermined period after the supply of the power supply voltage VDD is started, the interface circuit 170 directly sets the operation mode to the normal operation mode without setting the operation mode to the external communication mode after the predetermined period elapses.

The output circuit 151 outputs at least one output clock signal based on the oscillation signal Vosc output from the oscillation circuit 131. For example, the output circuit 151 includes a first buffer circuit 152 and a second buffer circuit 153. The first buffer circuit 152 outputs the first output clock signal CK1 based on the oscillation signal Vosc. The second buffer circuit 153 outputs the second output clock signal CK2 based on the oscillation signal Vosc. For example, the first buffer circuit 152 buffers the oscillation signal Vosc and outputs the first output clock signal CK1, and the second buffer circuit 153 buffers the oscillation signal Vosc and outputs the second output clock signal CK2. The first output clock signal CK1 and the second output clock signal CK2 may have the same frequency or different frequencies. The first output clock signal CK1 and the second output clock signal CK2 may have the same signal format or different signal formats. The first output clock signal CK1 is output to an outside via the PO1 terminal from the TO1 terminal. The second output clock signal CK2 is output to the outside via the PO2 terminal from the TO2 terminal. In FIG. 4, the output circuit 151 outputs the two output clock signals CK1 and CK2, and may output three or more output clock signals.

The output circuit 151 is a circuit that generates heat when the output circuit 151 operates, and operates in the first state or in the second state in which current consumption is different from that in the first state. That is, the output circuit 151 corresponds to the heat source circuit 150 shown in FIG. 1. A heat generation amount when the output circuit 151 operates in the first state is different from a heat generation amount when the output circuit 151 operates in the second state. In the embodiment, at least one external control signal is received from the outside of the vibrator device 1, and the first state and the second state of the output circuit 151 are switched based on the external control signal. For example, as at least one external control signal, the first enable control signal EN1 and the second enable control signal EN2 are received via the PE1 terminal and the PE2 terminal from the TE1 terminal and the TE2 terminal. In the output circuit 151, when the first enable control signal EN1 is active, the first buffer circuit 152 operates to output the first output clock signal CK1, and when the second enable control signal EN2 is active, the second buffer circuit 153 operates to output the second output clock signal CK2.

In the embodiment, the first state of the output circuit 151 is a state in which the first output clock signal CK1 is output, and the second state of the output circuit 151 is a state in which both the first output clock signal CK1 and the second output clock signal CK2 are output. That is, in the embodiment, in the first state of the output circuit 151, the first buffer circuit 152 outputs the first output clock signal CK1, and in the second state of the output circuit 151, the first buffer circuit 152 outputs the first output clock signal CK1, and the second buffer circuit 153 outputs the second output clock signal CK2.

Therefore, current consumption when the output circuit 151 operates in the second state is larger than current consumption when the output circuit 151 operates in the first state. Therefore, when the output circuit 151 switches from the first state to the second state, the heat generation amount of the output circuit 151 increases. Conversely, when the output circuit 151 switches from the second state to the first state, the heat generation amount of the output circuit 151 decreases.

When the heat generation amount of the output circuit 151 increases before and after switching between the first state and the second state of the output circuit 151, heat is propagated from the output circuit 151 to the temperature detection circuit 101 and the temperature of the temperature detection circuit 101 rises, and heat is propagated from the output circuit 151, via the package 4, to the vibrator 3 and the temperature of the vibrator 3 rises. Conversely, when the heat generation amount of the output circuit 151 decreases before and after switching between the first state and the second state of the output circuit 151, heat is propagated from the temperature detection circuit 101 to the output circuit 151 and the temperature of the temperature detection circuit 101 decreases, and heat is propagated from the vibrator 3, via the package 4, to the output circuit 151 and the temperature of the vibrator 3 decreases.

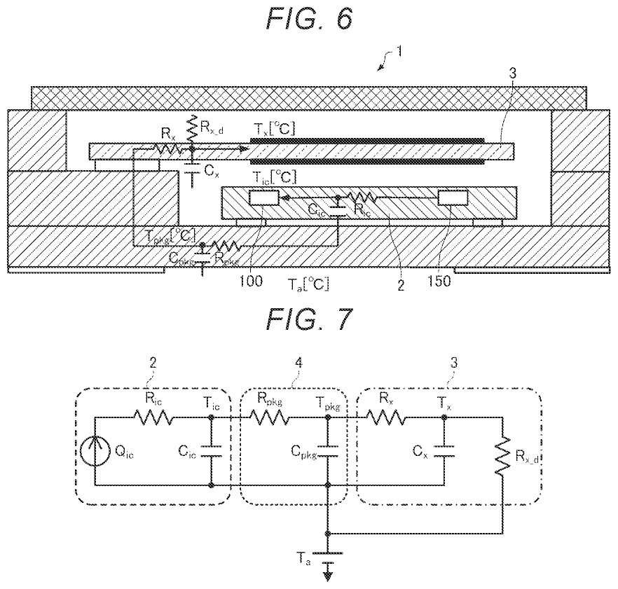

FIG. 6 shows a heat propagation path from the output circuit 151 to the temperature detection circuit 101 and a heat propagation path from the output circuit 151 to the vibrator 3 when the output circuit 151 is switched from the first state to the second state. FIG. 7 is a diagram showing a thermal network based on the propagation path in FIG. 6. In FIGS. 6 and 7, Q_{ic} is a heat flow rate generated by the output circuit 151. R_{ic}, C_{ic}, and T_{ic} are thermal resistance, a thermal capacity, and a temperature of the circuit device 2, respectively. R_{pkg}, C_{pkg}, and T_{pkg} are thermal resistance, a thermal capacity, and a temperature of the package 4, respectively. Rₓ, Cₓ, and Tₓ are thermal resistance, a thermal capacity, and a temperature of the vibrator 3, respectively. Tₐ is a temperature of the outside air.

As shown in FIG. 6, since the temperature sensor 100 and the output circuit 151 are in the circuit device 2, heat is rapidly propagated between the output circuit 151 and the temperature detection circuit 101 in the temperature sensor 100, whereas the circuit device 2 is disposed apart from the vibrator 3, heat is propagated via the package 4 between the output circuit 151 and the vibrator 3, and heat propagation becomes slow. Therefore, as shown in FIG. 7, a time constant of heat propagation between the output circuit 151 and the temperature detection circuit 101 is larger than a time constant of heat propagation between the output circuit 151 and the vibrator 3, and when the output circuit 151 is switched between the first state and the second state, a transient response of the temperature detected by the temperature detection circuit 101 is faster than a transient response of the temperature of the vibrator 3.

When the temperature signal DT output from the A/D conversion circuit 102 passes through the digital filter 111, a group delay occurs according to a cutoff frequency of the digital filter 111, and an input of the temperature signal DT to the temperature compensation circuit 120 is delayed. As a result, due to a time constant of the digital filter 111, a difference between the time constant of the heat propagation between the output circuit 151 and the temperature detection circuit 101 and the time constant of the heat propagation between the output circuit 151 and the vibrator 3 becomes small. Therefore, a difference between the transient response of the temperature detected by the temperature detection circuit 101 and the transient response of the temperature of the vibrator 3 is compensated for, and the temperature compensation accuracy attained by the temperature compensation circuit 120 is improved. That is, the digital filter 111 has a function of compensating for the difference between the transient response of the temperature detected by the temperature detection circuit 101 and the transient response of the temperature of the vibrator 3 when the first state and the second state of the output circuit 151 are switched, and corresponds to the transient response compensation circuit 110 shown in FIG. 1.

The digital filter 111 may operate at an order or a cutoff frequency based on data stored in the memory 140. That is, the order or the cutoff frequency of the digital filter 111 may be variable according to data stored in the memory 140 in advance. Accordingly, the time constant of the digital filter 111 can be finely adjusted, and compensation accuracy of a transient response by the digital filter 111 is improved. As a result, the temperature compensation accuracy attained by the temperature compensation circuit 120 is further improved.

When the temperature outside the package 4 of the vibrator device 1 changes, the difference between the heat propagation time between the temperature detection circuit 101 and the outside air and the heat propagation time between the vibrator 3 and the outside air is small. Therefore, when the digital filter 111 is always operating, and when the outside air temperature changes while the output circuit 151 is in the first state or the second state, excessive temperature compensation is performed by the temperature compensation circuit 120. Therefore, after the first state and the second state of the output circuit 151 are switched, it is preferable to stop an operation of the digital filter 111 after a predetermined period elapses. The predetermined period may be, for example, a period from when the output circuit 151 switches between the first state and the second state until the transient response of the temperature of the vibrator 3 converges.

### 2-1-3. Operation and Effect

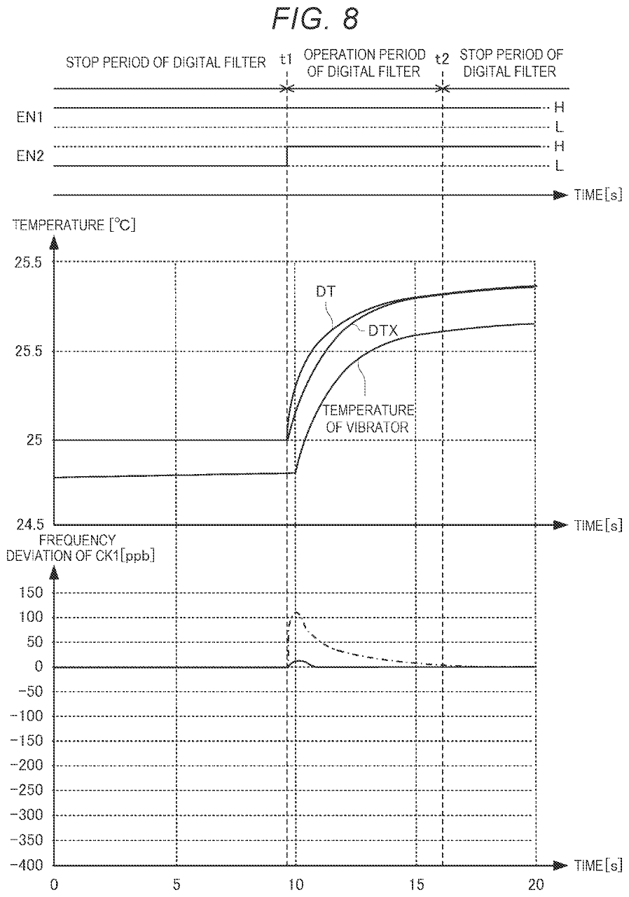

FIG. 8 is a diagram showing an example of changes over time in a transient response of a temperature indicated by the temperature signals DT and DTX, a transient response of a temperature of the vibrator 3, and a frequency deviation of the first output clock signal CK1 when the output circuit 151 is switched from the first state to the second state. In FIG. 8, a change over time of the frequency deviation of the first output clock signal CK1 in a vibrator device in a comparative example is also indicated by a one dot chain line. The vibrator device in the comparative example does not include the digital filter 111 in FIG. 4, and other configurations are the same as those in the vibrator device 1. In an example in FIG. 8, when the first enable control signal EN1 is active (high level), the second enable control signal EN2 changes from inactive (low level) to active (high level) at a time point t1. Therefore, the output circuit 151 operates in the first state before the time point t1, and the output circuit 151 operates in the second state after the time point t1. A heat generation amount of the output circuit 151 increases before and after the time point t1, and the temperature detected by the temperature detection circuit 101, that is, the temperature indicated by the temperature signal DT rises. Since the temperature of the vibrator 3 rises a little later thereafter, in the vibrator device according to the comparative example, the frequency deviation of the first output clock signal CK1 increases due to excessive temperature compensation applied in a period from the time point t1 to start of the temperature rise of the vibrator 3, and becomes 109 ppb at a peak. On the other hand, in the vibrator device 1 according to the embodiment, a peak of a frequency deviation of the first output clock signal CK1 is reduced to 18 ppb by applying appropriate temperature compensation based on the temperature signal DTX having a gentler slope than the temperature signal DT. In the example in FIG. 8, when a predetermined period from the time point t1 to a time point t2 elapses, an operation of the digital filter 111 is stopped in order to speed up a response to a change in the outside air temperature.

Thus, in the vibrator device 1 according to the first embodiment, when the first state and the second state of the output circuit 151 are switched, and when current consumption of the output circuit 151 changes and a heat generation amount rapidly changes, due to the change in the heat generation amount, the temperature detection circuit 101 in the circuit device 2 as well as the output circuit 151 quickly detects the temperature change, but a temperature change of the vibrator 3, which is separate from the circuit device 2, is delayed. However, according to the vibrator device 1 in the first embodiment, a rapid change in the temperature signal DT generated by the temperature detection circuit 101 becomes gentle by the digital filter 111. Therefore, the difference between the transient response of the temperature detected by the temperature detection circuit 101 and the transient response of the temperature of the vibrator 3 is compensated for, and even when the current consumption of the output circuit 151 rapidly changes, the temperature compensation circuit 120 can perform temperature compensation with high accuracy. Specifically, according to the vibrator device 1 in the first embodiment, even when the first state in which the first buffer circuit 152 outputs the first output clock signal CK1 and the second state in which the first buffer circuit 152 and the second buffer circuit 153 output the first output clock signal CK1 and the second output clock signal CK2, respectively, are switched by setting of the first enable control signal EN1 and the second enable control signal EN2, which are the external control signals, and the heat generation amount of the output circuit 151 is changed, the first output clock signal CK1 and the second output clock signal CK2 that are appropriately temperature-compensated for can be output.

According to the vibrator device 1 in the first embodiment, the order and the cutoff frequency of the digital filter 111 can be changed by changing the data stored in the memory 140, and the difference between the transient response of the temperature detected by the temperature detection circuit 101 and the transient response of the temperature of the vibrator 3 can be accurately compensated for, and as a result, accuracy of the temperature compensation is improved.

According to the vibrator device 1 in the first embodiment, when a transient situation after the switching between the first state and the second state of the output circuit 151 ends, the digital filter 111 stops the operation. Therefore, a possibility that the temperature compensation circuit 120 performs excessive temperature compensation against subsequent changes in outside air temperature is reduced.

### 2-2. Second Embodiment

Hereinafter, in a second embodiment, the same reference signs are given to similar configurations as those in the first embodiment, similar description as that in the first embodiment will be omitted or simplified, and contents different from those in the first embodiment will be mainly described.

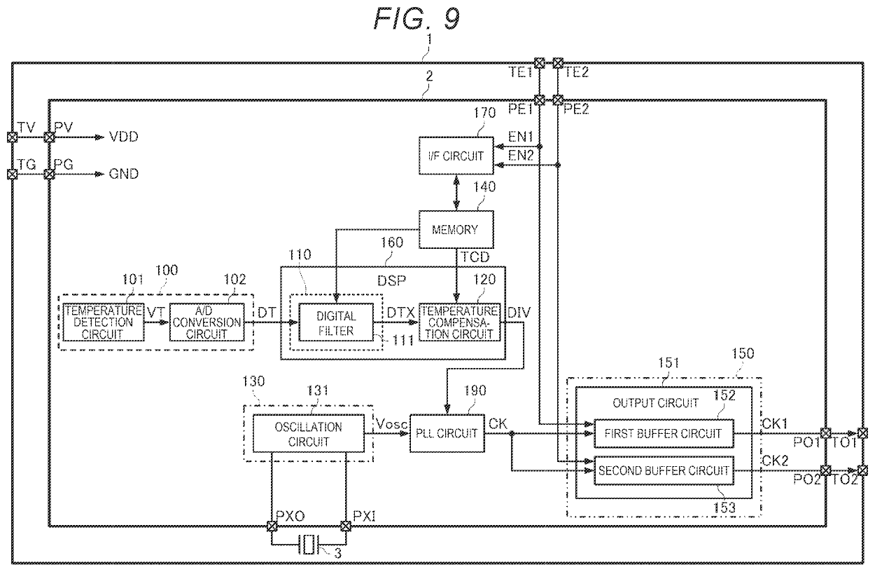

A structure of the vibrator device 1 according to the second embodiment is similar as that in FIGS. 2 and 3, and thus illustration and description thereof are omitted. FIG. 9 is a functional block diagram of the vibrator device 1 according to the second embodiment. As shown in FIG. 9, the vibrator device 1 according to the second embodiment is different from the vibrator device 1 according to the first embodiment shown in FIG. 4 in that the circuit device 2 includes a PLL circuit 190 and the temperature compensation circuit 120 outputs a frequency division ratio setting signal DIV, which is a digital signal indicating a frequency division ratio of the PLL circuit 190. The PLL is an abbreviation for phase locked loop. The oscillation circuit 131 may include the variable capacitance circuit 132 shown in FIG. 4 or may not include the variable capacitance circuit 132.

The PLL circuit 190 receives the oscillation signal Vosc and outputs a clock signal CK. The PLL circuit 190 generates the clock signal CK by performing feedback control such that a phase of the oscillation signal Vosc coincides with a phase of a signal obtained by frequency-dividing the clock signal CK at a frequency division ratio designated by the frequency division ratio setting signal DIV output from the temperature compensation circuit 120. The PLL circuit 190 may be an integer-type PLL circuit that frequency-divides the clock signal CK by an integer frequency division ratio or may be a fractional-N type PLL circuit that frequency-divides the clock signal CK by a fractional frequency division ratio.

The output circuit 151 outputs at least one output clock signal based on the clock signal CK output from the PLL circuit 190. Specifically, the clock signal CK output from the PLL circuit 190 is input to the first buffer circuit 152 and the second buffer circuit 153 of the output circuit 151. The first buffer circuit 152 buffers the clock signal CK and generates the first output clock signal CK1, and the second buffer circuit 153 buffers the clock signal CK and generates the second output clock signal CK2.

The temperature compensation circuit 120 compensates for, based on the temperature signal DTX output from the digital filter 111, frequency-temperature characteristics of the clock signal CK based on the oscillation signal Vosc as the temperature characteristics of the drive state of the vibrator 3. Specifically, the temperature compensation data TCD for compensating for the frequency-temperature characteristics of the clock signal CK is stored in the memory 140, and the temperature compensation circuit 120 generates, based on the temperature signal DTX and the temperature compensation data TCD, the frequency division ratio setting signal DIV that is a digital signal.

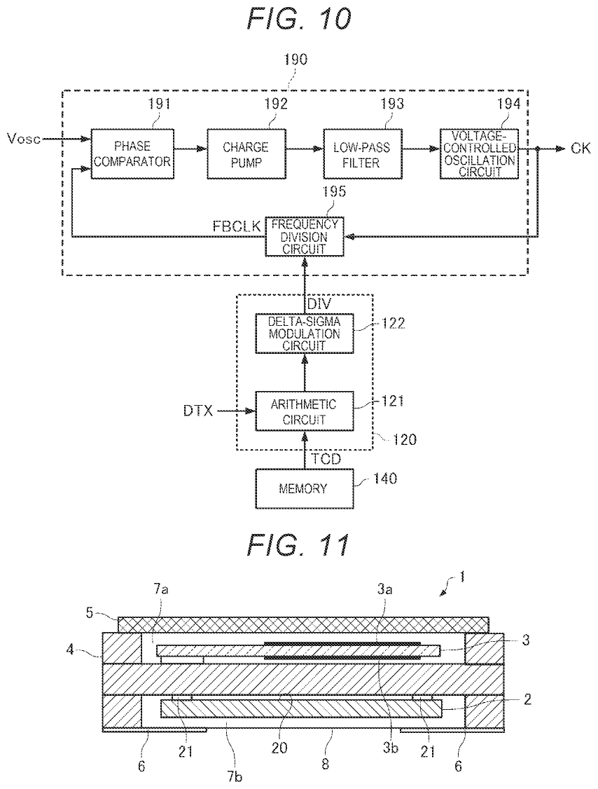

FIG. 10 is a diagram showing a configuration example of the temperature compensation circuit 120 and the PLL circuit 190. In the example in FIG. 10, the PLL circuit 190 is a fractional-N type PLL circuit.

As shown in FIG. 10, the temperature compensation circuit 120 includes an arithmetic circuit 121 and a delta-sigma modulation circuit 122. The PLL circuit 190 includes a phase comparator 191, a charge pump 192, a low-pass filter 193, a voltage-controlled oscillation circuit 194, and a frequency division circuit 195.

The arithmetic circuit 121 of the temperature compensation circuit 120 calculates, based on the temperature signal DTX output from the digital filter 111 and the temperature compensation data TCD stored in the memory 140, a frequency division ratio of the frequency division circuit 195 necessary for temperature compensation of the oscillation signal Vosc. Frequency division ratio setting data VDIV is data indicating the frequency division ratio of the frequency division circuit 195 set at a reference temperature, for example, 25° C., and the arithmetic circuit 121 performs a calculation for obtaining, based on the frequency division ratio setting data VDIV, the fractional frequency division ratio at the temperature indicated by the temperature signal DTX.

The delta-sigma modulation circuit 122 performs delta-sigma modulation on the fractional frequency division ratio that is an arithmetic result of the arithmetic circuit 121, and outputs the frequency division ratio setting signal DIV that sets the frequency division ratio of the frequency division circuit 195. A time average value of the frequency division ratio setting signal DIV coincides with the fractional frequency division ratio that is the arithmetic result of the arithmetic circuit 121.

The phase comparator 191 of the PLL circuit 190 compares the phase of the oscillation signal Vosc output from the oscillation circuit 131 with a phase of a clock signal FBCLK output from the frequency division circuit 195, and outputs a comparison result as a pulse voltage.

The charge pump 192 converts the pulse voltage output from the phase comparator 191 into a current. The low-pass filter 193 smooths the current output from the charge pump 192 and converts the smoothed current into a voltage.

The voltage-controlled oscillation circuit 194 uses the output voltage of the low-pass filter 193 as a control voltage, and outputs the clock signal CK whose frequency changes according to the control voltage. The voltage-controlled oscillation circuit 194 can be implemented as various types of oscillation circuits such as an LC oscillation circuit implemented using an inductance element such as a coil and a capacitance element such as a capacitor and an oscillation circuit using a piezoelectric resonator such as a quartz crystal resonator.

The frequency division circuit 195 outputs, using a value of the frequency division ratio setting signal DIV output from the delta-sigma modulation circuit 122 of the temperature compensation circuit 120 as the frequency division ratio, the clock signal FBCLK obtained by frequency-dividing the clock signal CK output from the voltage-controlled oscillation circuit 194.

The other configurations and functions of the vibrator device 1 in the second embodiment are similar as those in the first embodiment, and thus description thereof is omitted.

According to the vibrator device 1 in the second embodiment described above, similar effects as those of the vibrator device 1 in the first embodiment can be attained.

### 3. Modification

The present disclosure is not limited to the embodiment, and various modifications can be made within the scope of the gist of the present disclosure.

For example, the vibrator device 1 according to the above embodiments is not limited to the structure shown in FIGS. 2 and 3. The vibrator device 1 may have, for example, a structure shown in FIG. 11. In FIG. 11, similar components as those in FIG. 3 are denoted by the same reference signs. The vibrator device 1 shown in FIG. 11 is an oscillator having an H-shaped structure, the package 4 is formed with two recesses on opposite surfaces thereof, the lid 5 covers one recess to form a housing chamber 7a, and a sealing member 8 covers the other recess to form a housing chamber 7b. The vibrator 3 is housed in the housing chamber 7a, and the circuit device 2 is housed in the housing chamber 7b. In the vibrator device 1 having the H-shaped structure shown in FIG. 11, compared with the vibrator device having the single seal structure shown in FIG. 3, heat is less likely to propagate between the circuit device 2 and the vibrator 3 via a space, and the difference between the transient response of the temperature detected by the temperature sensor 100 and the transient response of the temperature of the vibrator 3 is larger. However, since the vibrator device 1 having the H-shaped structure shown in FIG. 11 includes the transient response compensation circuit 110, the difference between the transient response of the temperature detected by the temperature sensor 100 and the transient response of the temperature of the vibrator 3 is compensated for. Therefore, the temperature compensation can be performed with high accuracy.

In each of the above embodiments, the temperature compensated oscillator is taken as an example of the vibrator device 1, but a type of the vibrator device 1 is not limited thereto. For example, the vibrator device 1 maybe various physical quantity sensors such as a gyro sensor. As an example, the vibrator device 1 that is a physical quantity sensor includes a sensor element that is the vibrator 3 and the circuit device 2. The circuit device 2 includes the temperature sensor 100, the transient response compensation circuit 110 that compensates for a difference between a transient response of a temperature detected by the temperature sensor 100 and a transient response of a temperature of the sensor element, the temperature compensation circuit 120 that compensates for temperature characteristics of a drive state of the sensor element, the drive circuit 130 that drives the sensor element, a detection circuit that detects a predetermined physical quantity based on an output signal of the sensor element, and a failure detection circuit that is the heat source circuit 150. For example, the failure detection circuit is a circuit that detects a failure or the like of the sensor element. For example, among N times for which the detection circuit acquires the output signal of the sensor element, the failure detection circuit is in a first state in which failure detection is not performed N−1 times, and in a second state in which failure detection is performed once. Therefore, the failure detection circuit corresponds to the heat source circuit 150. As another example, the vibrator device 1 that is a three-axis physical quantity sensor includes a three-axis sensor element that is the vibrator 3 and the circuit device 2. The circuit device 2 includes the temperature sensor 100, the transient response compensation circuit 110 that compensates for a difference between a transient response of a temperature detected by the temperature sensor 100 and a transient response of a temperature of the three-axis sensor element, the temperature compensation circuit 120 that compensates for temperature characteristics of a drive state of the three-axis sensor element, the drive circuit 130 that drives the sensor element, and the detection circuit that detects a predetermined physical quantity in three axes based on an output signal of the three-axis sensor element. For example, when the drive circuit 130 switches between drive of a part of the three-axis sensor element and drive of the entire three-axis sensor element, the detection circuit switches between a first state in which detection is performed on output signals of a part of the sensor element and a second state in which detection is performed on output signals of the entire sensor element. Therefore, the detection circuit corresponds to the heat source circuit 150. According to the vibrator device 1 that is such a physical quantity sensor, detection accuracy of the physical quantity is improved by improving the temperature compensation accuracy.

The above embodiments and modification are examples, and the present disclosure is not limited thereto. For example, the embodiments and the modification may be combined as appropriate.

The present disclosure has substantially the same configurations as the configurations described in the embodiments, such as a configuration having the same function, method, and result or a configuration having the same object and effect. The present disclosure has a configuration in which a non-essential portion of the configuration described in the embodiments is replaced. The present disclosure has a configuration capable of achieving the same operation and effect or a configuration capable of achieving the same object as the configuration described in the embodiments. The present disclosure has a configuration obtained by adding a known technique to the configuration described in the embodiment.

The following contents are derived from the above embodiments and modification.

An aspect of a vibrator device including:
a vibrator; and
a circuit device disposed apart from the vibrator, in which
the circuit device includes
   a drive circuit configured to drive the vibrator,
   a temperature sensor configured to generate a temperature signal corresponding to a detected temperature,
   a temperature compensation circuit configured to compensate for temperature characteristics of a drive state of the vibrator based on the temperature signal,
   a heat source circuit configured to operate in a first state or in a second state in which current consumption is different from current consumption in the first state, and
   a transient response compensation circuit configured to compensate for, when the first state and the second state of the heat source circuit are switched, a difference between a transient response of a temperature detected by the temperature sensor and a transient response of a temperature of the vibrator.

In the vibrator device, when the first state and the second state of the heat source circuit are switched, and when current consumption of the heat source circuit changes and a heat generation amount rapidly changes, due to this change in the heat generation amount, the temperature sensor in the circuit device as well as the heat source circuit quickly detects the temperature change, but a temperature change in the vibrator, which is separate from the circuit device, is delayed. However, according to the vibrator device, by compensating for the difference between the transient response of the temperature detected by the temperature sensor and the transient response of the temperature of the vibrator, the temperature compensation circuit can perform the temperature compensation with high accuracy even when the current consumption of the heat source circuit rapidly changes.

In an aspect of the vibrator device,
the temperature signal may be a digital signal, and
the transient response compensation circuit may include a digital filter configured to perform filter processing on the temperature signal.

According to the vibrator device, the temperature signal generated by the temperature sensor is delayed by the digital filter. Therefore, the difference between the transient response of the temperature detected by the temperature sensor and the transient response of the temperature of the vibrator is compensated for.

In an aspect of the vibrator device,
the digital filter may be a low-pass filter.

According to the vibrator device, a rapid change in the temperature signal generated by the temperature sensor becomes gentle by the low-pass filter, and thus the difference between the transient response of the temperature detected by the temperature sensor and the transient response of the temperature of the vibrator is compensated for.

In an aspect of the vibrator device,
the digital filter may operate at a cutoff frequency based on data stored in a memory.

According to the vibrator device, the cutoff frequency of the digital filter can be changed by changing data stored in the memory, the difference between the transient response of the temperature detected by the temperature sensor and the transient response of the temperature of the vibrator can be accurately compensated for, and as a result, the accuracy of the temperature compensation is improved.

In an aspect of the vibrator device,
the transient response compensation circuit may stop operating after a predetermined period elapses after the first state and the second state of the heat source circuit are switched.

According to the vibrator device, when a transient situation after the switching between the first state and the second state of the heat source circuit ends, the transient response compensation circuit stops an operation. Therefore, a possibility that the temperature compensation circuit performs excessive temperature compensation against subsequent changes in outside air temperature is reduced.

In an aspect of the vibrator device,
the drive circuit may generate an oscillation signal by oscillating the vibrator,
the temperature compensation circuit may compensate for frequency-temperature characteristics of the oscillation signal or a clock signal based on the oscillation signal, and
the heat source circuit may be an output circuit that outputs at least one output clock signal based on the oscillation signal or the clock signal.

According to the vibrator device, by compensating for the difference between the transient response of the temperature detected by the temperature sensor and the transient response of the temperature of the vibrator, even when the current consumption of the output circuit changes and the heat generation amount rapidly changes, an output clock signal that is appropriately temperature-compensated for can be output.

In an aspect of the vibrator device,
at least one external control signal may be received, and the first state and the second state of the output circuit may be switched based on the external control signal.

According to the vibrator device, when the output circuit is switched between the first state and the second state by the external control signal and the heat generation amount is changed, the output clock signal that is appropriately temperature-compensated for can also be output.

In an aspect of the vibrator device,
a first enable control signal and a second enable control signal may be received as the at least one external control signal, and
the output circuit may
   output a first output clock signal when the first enable control signal is active, and
   output a second output clock signal when the second enable control signal is active.

According to the vibrator device, when the heat generation amount is changed by switching between the first state and the second state of the output circuit due to setting of the first enable control signal and the second enable control signal, the first output clock signal and the second output clock signal that are appropriately temperature-compensated for can also be output.

In an aspect of the vibrator device,
the first state may be a state in which the first output clock signal is output, and
the second state may be a state in which both the first output clock signal and the second output clock signal are output.

According to the vibrator device, when the first state in which the first output clock signal is output and the second state in which both the first output clock signal and the second output clock signal are output are switched and the heat generation amount of the output circuit is changed, the first output clock signal and the second output clock signal that are appropriately temperature-compensated for can also be output.

In an aspect of the vibrator device,
the output circuit may include
   a first buffer circuit configured to output the first output clock signal based on the oscillation signal, and
   a second buffer circuit configured to output the second output clock signal based on the oscillation signal,
in the first state, the first buffer circuit may output the first output clock signal, and
in the second state, the first buffer circuit may output the first output clock signal, and the second buffer circuit may output the second output clock signal.

According to the vibrator device, when the first state in which the first buffer circuit outputs the first output clock signal and the second state in which the first buffer circuit and the second buffer circuit output the first output clock signal and the second output clock signal, respectively, are switched and the heat generation amount of the output circuit is changed, the first output clock signal and the second output clock signal that are appropriately temperature-compensated for can also be output.

What is claimed is:

1. A vibrator device comprising:
a vibrator; and
a circuit device disposed apart from the vibrator, wherein
the circuit device includes
a drive circuit configured to drive the vibrator,
a temperature sensor configured to generate a temperature signal corresponding to a detected temperature,
a temperature compensation circuit configured to compensate for temperature characteristics of a drive state of the vibrator based on the temperature signal,
a heat source circuit configured to operate in a first state or in a second state in which current consumption is different from current consumption in the first state, and
a transient response compensation circuit configured to compensate for, when the first state and the second state of the heat source circuit are switched, a difference between a transient response of a temperature detected by the temperature sensor and a transient response of a temperature of the vibrator.

2. The vibrator device according to claim 1, wherein
the temperature signal is a digital signal, and
the transient response compensation circuit includes a digital filter configured to perform filter processing on the temperature signal.

3. The vibrator device according to claim 2, wherein
the digital filter is a low-pass filter.

4. The vibrator device according to claim 2, wherein
the digital filter operates at a cutoff frequency based on data stored in a memory.

5. The vibrator device according to claim 1, wherein
the transient response compensation circuit stops operating after a predetermined period elapses after the first state and the second state of the heat source circuit are switched.

6. The vibrator device according to claim 1, wherein
the drive circuit generates an oscillation signal by oscillating the vibrator,
the temperature compensation circuit compensates for frequency-temperature characteristics of the oscillation signal or a clock signal based on the oscillation signal, and
the heat source circuit is an output circuit that outputs at least one output clock signal based on the oscillation signal or the clock signal.

7. The vibrator device according to claim 6, wherein
at least one external control signal is received, and the first state and the second state of the output circuit are switched based on the external control signal.

8. The vibrator device according to claim 7, wherein
a first enable control signal and a second enable control signal are received as the at least one external control signal, and
the output circuit
outputs a first output clock signal when the first enable control signal is active, and
outputs a second output clock signal when the second enable control signal is active.

9. The vibrator device according to claim 8, wherein
the first state is a state in which the first output clock signal is output, and
the second state is a state in which both the first output clock signal and the second output clock signal are output.

10. The vibrator device according to claim 8, wherein
the output circuit includes
a first buffer circuit configured to output the first output clock signal based on the oscillation signal, and
a second buffer circuit configured to output the second output clock signal based on the oscillation signal,
in the first state, the first buffer circuit outputs the first output clock signal, and
in the second state, the first buffer circuit outputs the first output clock signal, and the second buffer circuit outputs the second output clock signal.
